(19) United States
(12) Patent Application Publication
(10) Pub. No.: US 2026/0223604 A1
(43) Pub. Date: Jul. 30, 2026

(54) Superconducting Planar Alternating Superconducting Gap Structures via Selective Seeding of Tantalum

(71) Applicant: Google LLC, Mountain View, CA (US)

(72) Inventors: George Earl Grant STERLING, Santa Barbara, CA (US); Lev IOFFE, Santa Barbara, CA (US); Lara FAORO, Santa Barbara, CA (US); Michael Clayton HAMILTON, Santa Barbara, CA (US); Sergey Nikolayevich VDOVICHEV, Camarillo, CA (US)

(21) Appl. No.: 19/040,317

(22) Filed: Jan. 29, 2025

(51) Int. Cl. H10N 60/85; H10N 60/01; H10N 60/12; H10N 60/80; H10N 69/00

(52) U.S. Cl. CPC H10N 60/85; H10N 60/0912; H10N 60/12; H10N 60/805; H10N 69/00

(57) ABSTRACT

A superconducting structure is provided. In one example, the superconducting layer includes a substrate, a patterned seed layer on the substrate and a superconducting layer on the patterned seed layer and the substrate. The superconducting layer includes a first portion with a first resistivity directly on the substrate and a second portion with a second resistivity directly on the patterned seed layer.

### FIELD

The present disclosure relates generally to systems and methods for quantum computing.

### BACKGROUND

Quantum computing is a computing method that takes advantage of quantum effects, such as superposition of basis states and entanglement to perform certain computations more efficiently than a classical digital computer. In contrast to a digital computer, which stores and manipulates information in the form of bits, e.g., a “1” or “0,” quantum computing systems can manipulate information using quantum bits (“qubits”). A qubit can refer to a quantum device that enables the superposition of multiple states, e.g., data in both the “0” and “1” state, and/or to the superposition of data, itself, in the multiple states. In accordance with conventional terminology, the superposition of a “0” and “1” state in a quantum system may be represented, e.g., as a|0 [symbol] +b|1 [symbol] The “0” and “1” states of a digital computer are analogous to the |0 [symbol] and |1 [symbol] basis states, respectively of a qubit.

### SUMMARY

Aspects and advantages of embodiments of the present disclosure will be set forth in part in the following description, or can be learned from the description, or can be learned through practice of the embodiments.

In one aspect, a superconducting structure is provided. The superconducting structure includes a substrate, a patterned seed layer on the substrate and a superconducting layer on the patterned seed layer and the substrate. The superconducting layer has a first portion with a first resistivity directly on the substrate and a second portion with a second resistivity directly on the patterned seed layer.

In another aspect, a method for forming a superconductor is provided. The method includes providing a substrate, providing a patterned seed layer on the substrate and providing a superconducting layer on the patterned seed layer and the substrate. The superconducting layer has first portion with a first resistivity directly on the substrate and a second portion with a second resistivity directly on the patterned seed layer.

In another aspect, a quantum computing system is provided. The quantum computing system includes a superconducting structure. The superconducting structure includes a substrate, a first superconductor layer on the substrate, a seed layer on the first superconductor layer and a second superconductor layer on the seed layer. The first superconductor layer has a first resistivity and the second superconductor layer has a second resistivity.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, explain the related principles.

### BRIEF DESCRIPTION OF THE DRAWINGS

Detailed discussion of embodiments directed to one of ordinary skill in the art is set forth in the specification, which refers to the appended figures, in which:

FIG. 1 depicts an example quantum computing system according to example embodiments of the present disclosure;

FIG. 2A depicts an example superconducting structure according to example embodiments of the present disclosure;

FIG. 2B depicts an example superconducting structure according to example embodiments of the present disclosure;

FIG. 3 depicts a cross-section view of an example superconducting structure according to example embodiments of the present disclosure;

FIG. 4 depicts an example superconducting structure according to example embodiments of the present disclosure;

FIG. 5 depicts an example superconducting structure according to example embodiments of the present disclosure;

FIG. 6 depicts an example superconducting structure according to example embodiments of the present disclosure;

FIG. 7 depicts an example superconducting structure according to example embodiments of the present disclosure;

FIG. 8 depicts an example resonator structure according to example embodiments of the present disclosure;

FIG. 9 depicts an example resonator structure according to example embodiments of the present disclosure;

FIG. 10 depicts an example resonator structure according to example embodiments of the present disclosure;

FIG. 11 depicts an example superconducting structure according to example embodiments of the present disclosure;

FIG. 12 depicts an example flow diagram of an example method according to example embodiments of the present disclosure.

### DETAILED DESCRIPTION

Example aspects of the present disclosure are directed to systems and methods for fabricating a superconducting structure, such as a superconducting structure used in a quantum computing system. The development of methods and structures to locally control the superconducting gap of a superconductor may be useful for building relevant structures for quantum computing. Superconducting gap variations may be achieved in aluminum by adjusting thickness, however, this is limiting because the thickness must be less than 20 nanometers to realize large differences in superconducting gap. Alternatively, superconducting gap variations may be achieved by oxygen or silicon doping of aluminum. However, doping may be difficult to control. Aspects of the present disclosure overcome these constraints and provide the realization of controllable superconducting gap variations in superconducting structures.

For instance, example aspects of the present disclosure provide a superconducting structure for use with, for instance, a quantum computing system. The superconducting structure may comprise a substrate. The superconducting structure may further comprise a patterned seed layer on the substrate. Furthermore, the superconducting structure may comprise a superconducting layer on the patterned seed layer and the substrate. The superconducting layer may have a first portion with a first resistivity and/or a first superconducting gap directly on the substrate and a second portion with a second resistivity and/or a second superconducting gap directly on the seed layer. The first resistivity and/or first superconducting gap may be different than the second resistivity and/or second superconducting gap. For instance, the first resistivity may be greater than the second resistivity. The superconducting layer may be superconducting at a temperature of less than 3k.

As used herein, a structure is “on” another structure when it is directly on the structure or if intervening structures are present. In contrast, a structure is “directly on” another structure if there are no intervening structures.

For instance, the patterned seed layer may be tantalum nitride, chromium, niobium, alpha phase tantalum nitride or sapphire. The superconducting layer may be tantalum, where the first portion is beta phase tantalum and the second portion is alpha phase tantalum. The substrate may be a silicon substrate or other suitable substrate.

The seed layer and first portion of the superconductor layer with first resistivity (e.g., beta phase tantalum) may have any suitable pattern on the substrate. For instance, the seed layer and first portion with first resistivity (e.g., beta phase tantalum) may have a hexagonal pattern, banded pattern, checkerboard pattern, or other suitable pattern.

The pattern may be used to form superconductor-based structures for use in, for instance, quantum computing systems. For instance, the superconducting structure may be a quasiparticle or phonon trap. For instance, the superconducting structure may be a resonator.

Example aspects of the present disclosure provide a method for forming a superconductor. The method may comprise providing a substrate. The method may further comprise providing a patterned seed layer on top of the substrate. Furthermore, the method may comprise providing a superconducting layer on top of the patterned seed layer and the substrate. The superconducting layer may have a first portion with a first resistivity and/or first superconducting gap directly on the substrate and a second portion with a second resistivity and/or second superconducting gap directly on the patterned seed layer.

Example aspects of the present disclosure provide a quantum computing system. The quantum computing system may comprise a superconducting structure. The superconducting structure may comprise a substrate. The superconducting structure may further comprise a patterned seed layer on top of the substrate. Furthermore, the superconducting structure may comprise a tantalum layer on the patterned seed layer. The tantalum layer may have a first portion with a first resistivity directly on the substrate and a second portion with a second resistivity directly on the patterned seed layer. The first portion may be beta phase tantalum and the second portion may be alpha phase tantalum.

Systems and methods, according to example aspects of the present disclosure can provide for a number of technical effects and benefits, including but not limited to improvements to computing technology (e.g., quantum computing technology). In some examples, aspects of the present disclosure may provide for compact resonator structures for quantum computing systems. For instance, lithography may be used to pattern tantalum nitride or other seed layer onto a substrate. The pattern may allow beta phase tantalum and/or alpha phase tantalum to grow on the substrate and the patterned seed layer. The technique may be used to make on-chip quasiparticle and on-chip phonon traps. By replacing control wiring and resonating structures with beta phase tantalum, one may be able to take advantage of the low superconducting gap of beta phase tantalum for down conversion of high energy photons. Furthermore, the superconducting gap of beta phase tantalum is about seven times lower than that of alpha phase tantalum and about half that of aluminum, which allows construction of high Q factor resonator structures. The high disorder and resultant high kinetic inductivity of beta phase tantalum may provide for the lower superconducting gap. The beta phase tantalum may shorten the length of structures. Furthermore, the higher superconducting gap regions of alpha phase tantalum in combination with beta phase tantalum may prevent quasiparticles in the lower superconducting gap beta phase tantalum film from participating in the current which would otherwise spoil the Q factor for the resonator structure.

For instance, example aspects of the present disclosure provide for high Q factor compact resonator structures. The beta phase tantalum may provide the technical benefit of shortening the length of structures. The alpha phase tantalum in combination with the beta phase tantalum may provide the benefit of preventing quasiparticles from participating in the current. By preventing the quasiparticles participating in the current, a higher Q factor may be maintained. Furthermore, by providing a phonon trap, a higher Q factor may be maintained.

In some examples, a superconductor structure may include a vertical stack. For instance, the superconductor structure may include a substrate. A first superconductor layer having a first superconducting gap and a first resistivity may be on the substrate (e.g., directly on the substrate). The first superconductor layer may be, for instance, beta phase tantalum. A seed layer may be on the first superconductor layer. The seed layer may be, for instance, tantalum nitride, chromium, niobium, alpha phase tantalum, alpha phase tantalum nitride, or sapphire. A second superconductor layer may be on the seed layer (e.g., directly on the seed layer). The second superconductor layer may have a second superconducting gap that is different from the first superconducting gap. The second layer may have a second resistivity that is different than the first resistivity.

With reference now to the Figures, example embodiments of the present disclosure will be discussed in further detail.

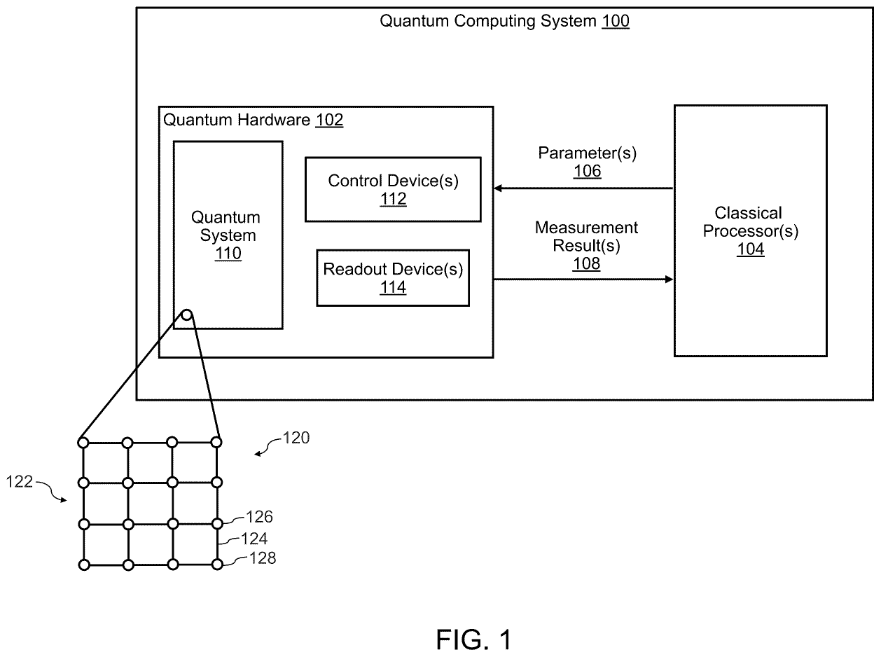

FIG. 1 depicts an example quantum computing system 100 in which superconducting structures according to example embodiments of the present disclosure may be implemented. The system 100 is an example of a system of one or more classical computers and/or quantum computing devices in one or more locations, in which the systems, components, and techniques described below can be implemented. Those of ordinary skill in the art, using the disclosures provided herein, will understand that other quantum computing devices or systems can be used without deviating from the scope of the present disclosure.

The system 100 includes quantum hardware 102 in data communication with one or more classical processors 104. The classical processors 104 can be configured to execute computer-readable instructions stored in one or more memory devices to perform operations, such as any of the operations described herein. The quantum hardware 102 includes components for performing quantum computation. For example, the quantum hardware 102 includes a quantum system 110, control device(s) 112, and readout device(s) 114 (e.g., readout resonator(s)). The quantum system 110 can include one or more multi-level quantum subsystems, such as a register of qubits (e.g., qubits 120). In some implementations, the multi-level quantum subsystems can include superconducting qubits, such as flux qubits, charge qubits, transmon qubits, gmon qubits, spin-based qubits, and the like. In some implementations, the superconducting qubits may be located in a cryostat to cool the qubits to superconducting temperatures (e.g., less than about 3 Kelvin). However, aspects of the present disclosure are not limited to superconducting qubits. In some examples, any suitable qubit structure may be used without deviating from the scope of the present disclosure, such as photonic qubits, trapped ion qubits, spin qubits, neutral atom qubits, quantum dot qubits, molecular qubits, or other qubits.

The type of multi-level quantum subsystems that the system 100 utilizes may vary. For example, in some cases the system may include one or more readout device(s) 114 coupled (e.g., electromagnetically coupled) to one or more qubits, e.g., transmon, flux, gmon, xmon, or other qubits. In other cases, ion traps, photonic devices or superconducting cavities (e.g., with which states may be prepared without requiring qubits) may be used. Further examples of realizations of multi-level quantum subsystems include fluxmon qubits, silicon quantum dot, or phosphorus impurity qubits.

Quantum circuits may be constructed and applied to the register of qubits included in the quantum system 110 via multiple control lines that are coupled to one or more control devices 112. Example control devices 112 that operate on the register of qubits can be used to implement quantum gates or quantum circuits having a plurality of quantum gates, e.g., Pauli gates, Hadamard gates, controlled-NOT (CNOT) gates, controlled-phase gates, T gates, multi-qubit quantum gates, coupler quantum gates, etc. The one or more control devices 112 may be configured to operate on the quantum system 110 through one or more respective control parameters (e.g., one or more physical control parameters). For example, in some implementations, the multi-level quantum subsystems may be superconducting qubits and the control devices 112 may be configured to provide control pulses to control lines to generate magnetic fields to control the qubits. For example, in some implementations the multi-level quantum subsystems may be neutral atom qubits and the control devices 112 may be configured to provide control pulses to control lines to generate magnetic fields to control the qubits.

The quantum hardware 102 may further include readout devices 114 (e.g., readout resonators). Measurement results 108 obtained via readout devices 114 may be provided to the classical processors 104 for processing and analyzing. In some implementations, the quantum hardware 102 may include a quantum circuit and the control device(s) 112 and readout devices(s) 114 may implement one or more quantum logic gates that operate on the quantum system 102 through physical control parameters (e.g., microwave pulses) that are sent through wires included in the quantum hardware 102. The readout device(s) 114 may be configured to perform quantum measurements on the quantum system 110 and send measurement results 108 to the classical processors 104.

In addition, the quantum hardware 102 may be configured to receive data specifying physical control qubit parameter values 106 from the classical processors 104. The quantum hardware 102 may use the received physical control qubit parameter values 106 to update the action of the control device(s) 112 and readout devices(s) 114 on the quantum system 110. For example, the quantum hardware 102 may receive data specifying new values representing voltage strengths of one or more DACs included in the control devices 112 and may update the action of the DACs on the quantum system 110 accordingly. The classical processors 104 may be configured to initialize the quantum system 110 in an initial quantum state, e.g., by sending data to the quantum hardware 102 specifying an initial set of parameters 106.

In some implementations, the readout device(s) 114 can take advantage of a difference in the impedance for the |0 [symbol] and |1 [symbol] states of an element of the quantum system, such as a qubit, to measure the state of the element (e.g., the qubit). For example, the resonance frequency of a readout resonator can take on different values when a qubit is in the state |0 [symbol] or the state |1 [symbol] , due to the nonlinearity of the qubit. Therefore, a microwave pulse reflected from the readout device 114 carries an amplitude and phase shift that depend on the qubit state. In some implementations, a Purcell filter can be used in conjunction with the readout device(s) 114 to impede microwave propagation at the qubit frequency.

In some embodiments, the quantum system 110 can include a plurality of qubits 120 arranged, for instance, in a two-dimensional grid 122. For clarity, the two-dimensional grid 122 depicted in FIG. 1 includes 4×4 qubits, however in some implementations the system 110 may include a smaller or a larger number of qubits. In some embodiments, the multiple qubits 120 can interact with each other through multiple qubit couplers, e.g., qubit coupler 124. The qubit couplers can define nearest neighbor interactions between the multiple qubits 120. In some implementations, the strengths of the multiple qubit couplers are tunable parameters. In some cases, the multiple qubit couplers included in the quantum computing system 100 may be couplers with a fixed coupling strength.

In some implementations, the multiple qubits 120 may include data qubits, such as qubit 126 and measurement qubits, such as qubit 128. A data qubit is a qubit that participates in a computation being performed by the system 100. A measurement qubit is a qubit that may be used to determine an outcome of a computation performed by the data qubit. That is, during a computation an unknown state of the data qubit is transferred to the measurement qubit using a suitable physical operation and measured via a suitable measurement operation performed on the measurement qubit.

In some implementations, each qubit in the multiple qubits 120 can be operated using respective operating frequencies, such as an idling frequency and/or an interaction frequency and/or readout frequency and/or reset frequency. The operating frequencies can vary from qubit to qubit. For instance, each qubit may idle at a different operating frequency. The operating frequencies for the qubits 120 can be chosen before a computation is performed. In some examples, the operating of the frequencies for the qubits 120 may be adjusted using AC Stark shift according to examples of the present disclosure before a quantum computation, quantum gate, and/or a quantum algorithm is performed.

FIG. 1 depicts one example quantum computing system that can be used to implement the methods and operations according to example aspects of the present disclosure. Other quantum computing systems can be used without deviating from the scope of the present disclosure.

In various implementations, the example system 100 can be implemented as a client device, a server device, or both. The example system 100 can be implemented as part of a distributed computing system. The example system 100 can be implemented along with other example systems, which may be the same or different. The example system 100 can be implemented in a server farm or other facility that operates multiple computing systems to provide computational services to or on behalf of a plurality of client systems. Advantageously, techniques according to example aspects of the present disclosure can provide for improved calibration and maintenance of computing facilities, increasing service uptime, decreasing failure rates, etc.

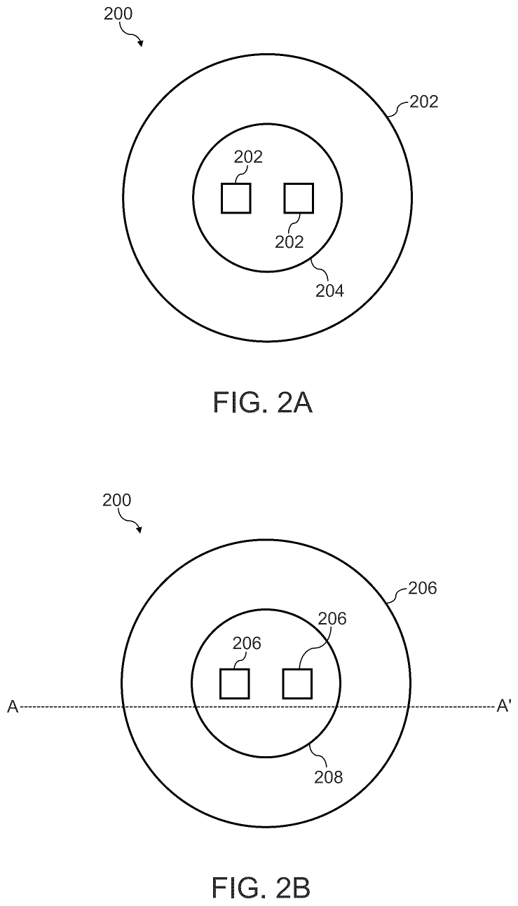

FIGS. 2A and 2B depict an example superconducting structure 200 that may be used, for instance, in the quantum computing system 100 of FIG. 1 according to example embodiments of the present disclosure. FIG. 2A depicts the superconducting structure 200 at a first stage of fabrication. FIG. 2B depicts the superconducting structure 200 at a second stage of fabrication. Referring to FIG. 2A, the superconducting structure 200 may include a substrate 202 and a seed layer 204. The substrate 202 may be, for instance, a semiconductor wafer and may act as a growth surface and/or deposition surface for the superconducting structure 200. The substrate 202 may include silicon, sapphire, germanium, or other suitable material.

The seed layer 204 may act as a seed for growth and/or deposition of a superconductor layer (e.g., tantalum). The seed layer 204 may be a patterned seed layer. The seed layer 204 may be tantalum, tantalum nitride, chromium, niobium, alpha phase tantalum, alpha phase tantalum nitride, or sapphire. The seed layer 204 may have any suitable pattern without deviating from the scope of the present disclosure. Example patterns are illustrated in FIGS. 4-6. The seed layer 204 may be patterned by lithography and etch, lithography and liftoff, lithography, or other suitable method.

A superconducting layer may be provided on the substrate 202 as shown in FIG. 2B. The superconducting structure 200 may include a first portion 206 with a first resistivity and/or a first superconducting gap and a second portion 208 with a second resistivity and/or a second superconducting gap. The first resistivity may be different from the second resistivity. The first superconducting gap may be different from the second superconducting gap.

The first portion 206 may be deposited on/grown directly on the substrate 202 (without the seed layer 204). The second portion 208 may be the portion of the superconducting layer that is deposited on the seed layer 204. The first portion 206 and the second portion 208 may be superconducting at temperatures of less than about 3K.

In some embodiments, the superconducting layer may be a tantalum layer. The first portion 206 may be, for instance, beta phase tantalum. The first portion 206 may be directly on the substrate 202. The second portion 208 may be, for instance, alpha phase tantalum. The second portion 208 may be directly on the seed layer 204. Alpha phase tantalum may have a resistivity of about 10 microohm-centimeters to about 20 microohm-centimeters at temperatures below about 3 Kelvin. Beta phase tantalum may have a resistivity in a range of about 150 microohm-centimeters to about 200 microohm-centimeters at temperatures below about 3 Kelvin. Beta phase tantalum may have a superconducting gap that is different from alpha phase tantalum, such as about seven times less than alpha phase tantalum.

The pattern may allow beta phase tantalum and/or alpha phase tantalum to grow on the substrate 202 and the seed layer 204 to provide superconducting structures used in, for instance, quantum computing systems. The pattern of the seed layer 204 may be used to make on-chip quasiparticle and on-chip phonon traps. The traps may utilize the low superconducting gap of beta phase tantalum for down conversion of high energy photons. Furthermore, as the superconducting gap of beta phase tantalum is about seven times lower than that of alpha phase tantalum and about half that of aluminum, high Q resonator structures may be constructed. The high disorder and resultant high kinetic inductivity of beta phase tantalum may provide for the lower superconducting gap. The beta phase tantalum may shorten the length of structures. Furthermore, the higher superconducting gap regions of alpha phase tantalum in combination with beta phase tantalum may prevent quasiparticles in the lower superconducting gap beta phase tantalum film from participating in the current which would otherwise spoil the Q factor for the resonator structure.

In some examples, after the first portion 206 and the second portion 208 are grown the superconducting structure 200 may be cleaned. The cleaning may be a mill cleaning, ion mill cleaning, or other suitable method.

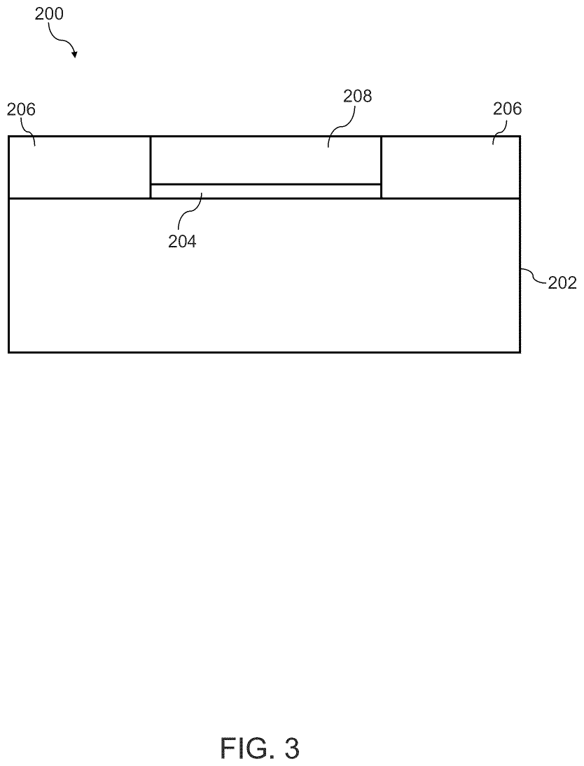

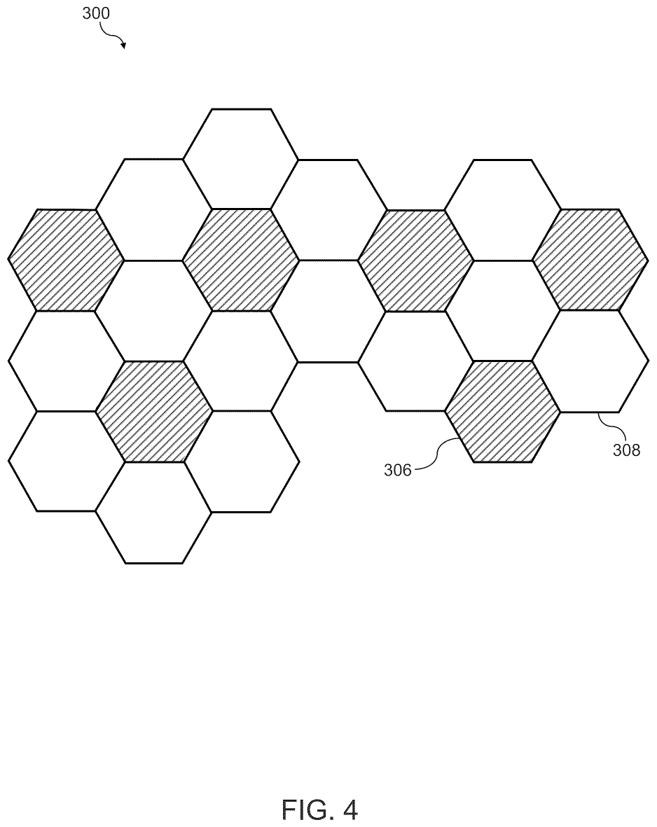

FIG. 3 depicts a cross-section view of an example superconducting structure 200 along line A-A′ of FIG. 2B. The superconducting structure 200 may include a substrate 202, a seed layer 204, and a superconducting layer including a first portion 206 and a second portion 208. The substrate 202 may be, for instance, a semiconductor wafer and may act as a growth surface and/or deposition surface for the superconducting structure 200. The substrate 202 may include silicon, sapphire, germanium, or other suitable material.

The seed layer 204 may act as a seed for growth and/or deposition of a superconductor layer (e.g., tantalum). The seed layer 204 may be a patterned seed layer. The seed layer 204 may be tantalum, tantalum nitride, chromium, niobium, alpha phase tantalum, alpha phase tantalum nitride, or sapphire. The seed layer 204 may have any suitable pattern without deviating from the scope of the present disclosure. Example patterns are illustrated in FIGS. 4-6. The seed layer 204 may be patterned by lithography and etch, lithography and liftoff, lithography, or other suitable method.

A superconducting layer may be provided on the substrate 202 as shown in FIG. 2B. The superconducting structure 200 may include a first portion 206 with a first resistivity and/or a first superconducting gap and a second portion 208 with a second resistivity and/or a second superconducting gap. The first resistivity may be different from the second resistivity. The first superconducting gap may be different from the second superconducting gap.

The first portion 206 may be deposited on/grown directly on the substrate 202 (without the seed layer 204). The second portion 208 may be the portion of the superconducting layer that is deposited on the seed layer 204. The first portion 206 and the second portion 208 may be superconducting at temperatures of less than about 3K.

In some embodiments, the superconducting layer may be a tantalum layer. The first portion 206 may be, for instance, beta phase tantalum. The first portion 206 may be directly on the substrate 202. The second portion 208 may be, for instance, alpha phase tantalum. The second portion 208 may be directly on the seed layer 204. Alpha phase tantalum may have a resistivity of about 10 microohm-centimeters to about 20 microohm-centimeters at temperatures below about 3 Kelvin. Beta phase tantalum may have a resistivity in a range of about 150 microohm-centimeters to about 200 microohm-centimeters at temperatures below about 3 Kelvin. Beta phase tantalum may have a superconducting gap that is different from alpha phase tantalum, such as about seven times less than alpha phase tantalum.

The pattern may allow beta phase tantalum and/or alpha phase tantalum to grow on the substrate 202 and the seed layer 204 to provide superconducting structures used in, for instance, quantum computing systems. The pattern of the seed layer 204 may be used to make on-chip quasiparticle and on-chip phonon traps. The traps may utilize the low superconducting gap of beta phase tantalum for down conversion of high energy photons. Furthermore, as the superconducting gap of beta phase tantalum is about seven times lower than that of alpha phase tantalum and about half that of aluminum, high Q resonator structures may be constructed. The high disorder and resultant high kinetic inductivity of beta phase tantalum may provide for the lower superconducting gap. The beta phase tantalum may shorten the length of structures. Furthermore, the higher superconducting gap regions of alpha phase tantalum in combination with beta phase tantalum may prevent quasiparticles in the lower superconducting gap beta phase tantalum film from participating in the current which would otherwise spoil the Q factor for the resonator structure.

In some examples, after the first portion 206 and the second portion 208 are grown the superconducting structure 200 may be cleaned. The cleaning may be a mill cleaning, ion mill cleaning, or other suitable method.

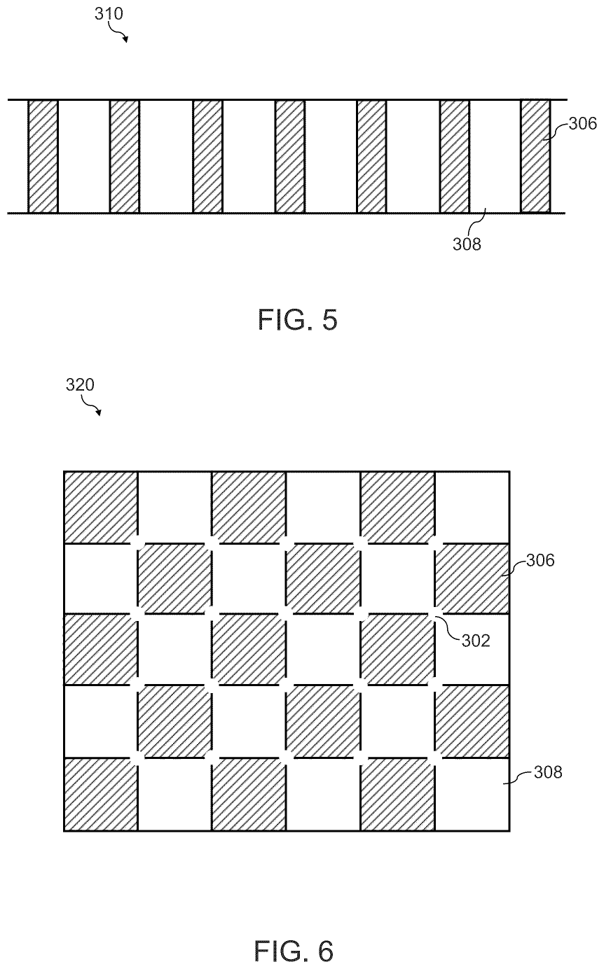

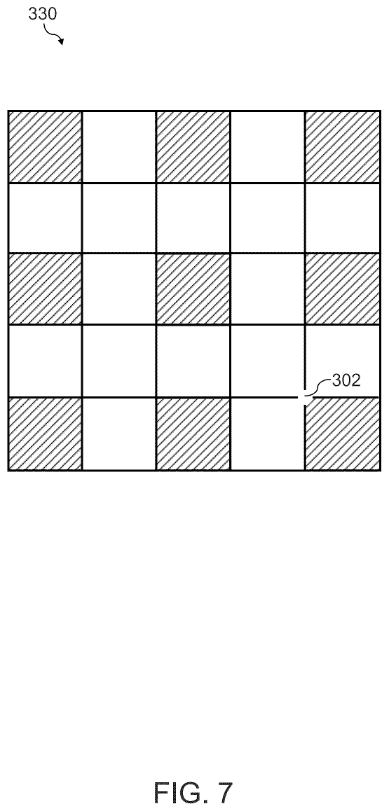

FIGS. 4-7 depict example superconducting structures according to example embodiments of the present disclosure. The superconducting structure may have a patterned seed layer (e.g., 300, 310, 320). The patterned seed layer may have a first portion 306 and a second portion 308. The first portion 306 may have a first resistivity and/or a first superconducting gap. The second portion 308 may have a second resistivity and/or a second superconducting gap. The first portion 306 may be beta phase tantalum. The second portion 308 may be alpha phase tantalum. The patterned seed layer 300 of FIG. 4 may be in a hexagonal pattern. The patterned seed layer 310 of FIG. 5 may be a banded pattern. The patterned seed layer 320 of FIG. 6 may be in a checkerboard pattern. The breaks 302 in the lines of the checkerboard may allow current to flow. The patterned seed layer 330 of FIG. 7 may be in a checkerboard pattern. The break 302 in the line of the checkerboard may allow current to flow. Other example patterns include, but a re not limited to, a zig zag pattern, a concentric circular pattern, a dotted pattern, a wave pattern, etc.

It should be understood that the patterns depicted in FIGS. 4-7 are provided for purposes of illustration and discussion. Any suitable pattern may be used without deviating from the scope of the present disclosure. In addition, the ratio of surface area of the first portion 306, and the second portion 308 may be adjusted in any suitable manner. Those of ordinary skill in the art, using the disclosures provided herein, would recognize that the ratio of the first portion 306 to the second portion 308 are not constrained by the pattern and that the first portion 306 may be the majority part of the pattern or that the second portion 308 may be the majority part of the pattern or that the first portion 306 and the second portion 308 may be equally split. In addition, the break 302 as depicted in FIGS. 6-7 may be at any part of the patterned seed layer, the break 302 may be in any shape. The break 302 may appear in any pattern (e.g., FIGS. 4-5).

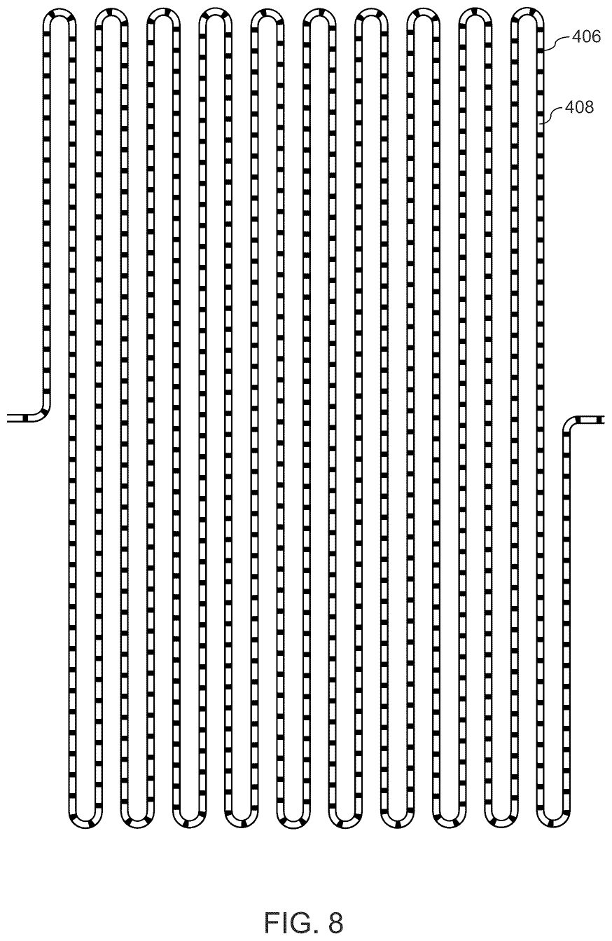

Aspects of the present disclosure may be used to fabricate structures used for quantum computing devices, such as resonator structures. FIG. 8 depicts an example resonator structure 400. The resonator structure 400 may be patterned according to the above embodiments. As shown the resonator structure 400 is in a banded pattern. The resonator structure 400 may include a first portion 406 and a second portion 408. The first portion 406 may be, for instance, beta phase tantalum. The second portion 408 may be, for instance, alpha phase tantalum. The resonator structure 400 may be a readout resonator. The resonator structure 400 may be a quasiparticle and/or phonon trap. The resonator structure 400 may be characterized by a difference in superconducting gap and/or resistivity between the first portion 406 and the second portion 408.

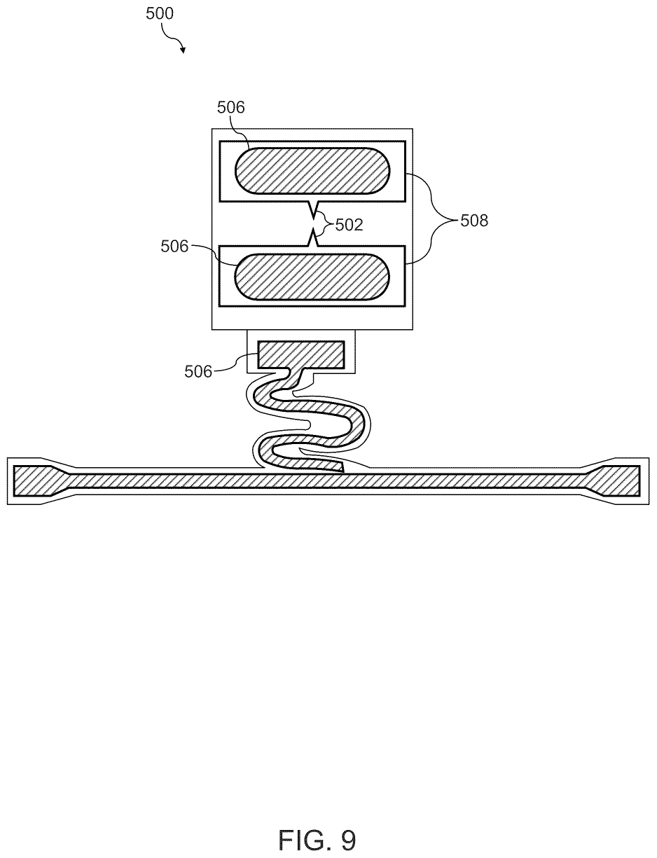

FIG. 9 depicts an example resonator structure 500. The resonator structure 500 may be patterned according to the above embodiments. The resonator structure 500 may include transmon paddles 502, a first portion 506 and a second portion 508. The transmon paddles 502 may be, for instance, aluminum. The first portion 506 may be, for instance, beta phase tantalum. The second portion 508 may be, for instance, alpha phase tantalum. The resonator structure 500 may be a readout resonator. The resonator structure 500 may be a quasiparticle and/or phonon trap. The resonator structure 500 may be characterized by a difference in superconducting gap and/or resistivity between the first portion 506 and the second portion 508.

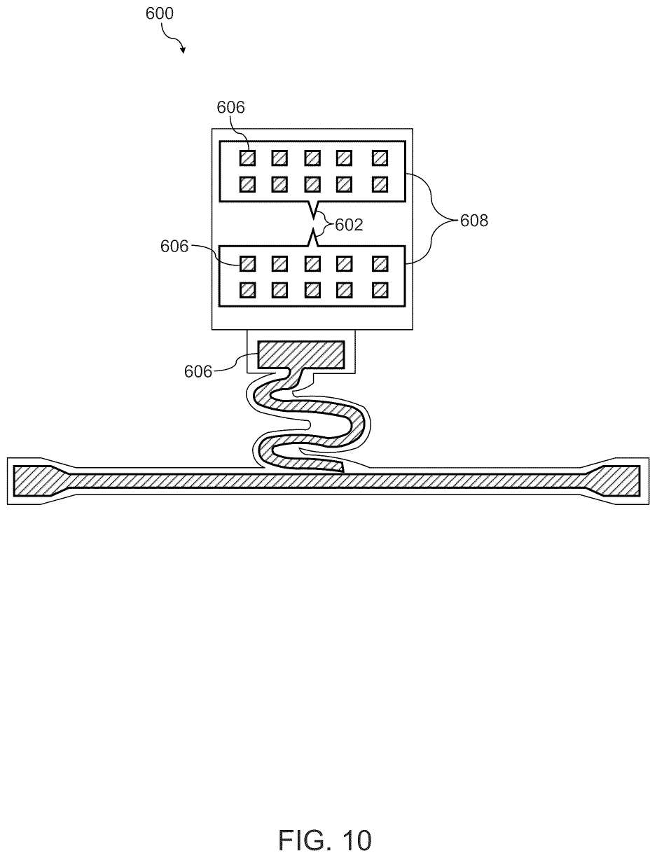

FIG. 10 depicts an example resonator structure 600. The resonator structure 600 may be patterned according to the above embodiments. The resonator structure 600 may include transmon paddles 602, a first portion 606 and a second portion 608. The transmon paddles 602 may be, for instance, aluminum. The first portion 606 may be, for instance, beta phase tantalum. The second portion 608 may be, for instance, alpha phase tantalum. The resonator structure 600 may be a readout resonator. The resonator structure 600 may be characterized by a difference in superconducting gap and/or resistivity between the first portion 606 and the second portion 608. The first portion(s) 606 (e.g., beta phase tantalum) may provide isolated regions for quasiparticles. The resonator structure 600 may be a quasiparticle trap and/or phonon trap.

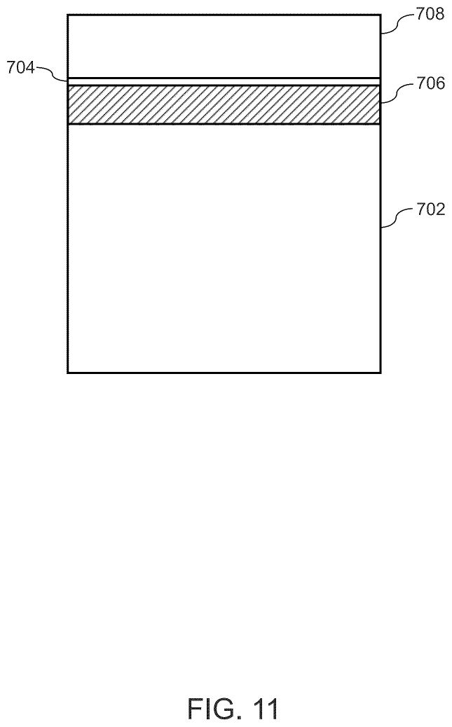

FIG. 11 depicts an example superconducting structure 700 that includes a vertical stack. The superconducting structure 700 may include a substrate 702, a seed layer 704, a first superconductor layer 706 with a first resistivity and/or first superconducting gap and a second superconductor layer 708 with a second resistivity and/or second superconducting gap.

The substrate 702 may be, for instance, a semiconductor wafer and may act as a growth surface and/or deposition surface for the second superconducting layer 708. The substrate 702 may include silicon, sapphire, germanium, or other suitable material.

The first superconductor layer 706 may be on the substrate 702. In some embodiments, the first superconductor layer 706 is beta phase tantalum. The first superconductor layer 706 may have a resistivity in a range of about 150 microohm-centimeters to about 200 microohm-centimeters at temperatures below about 3 Kelvin. The first superconductor layer 706 may have a thickness of about 15 nm or less.

A seed layer 704 may be on the first superconductor layer 706. The seed layer 704 may act as a seed for growth and/or deposition of a second superconductor layer 708 (e.g., alpha phase tantalum). The seed layer 704 may be tantalum nitride, chromium, niobium, alpha phase tantalum, alpha phase tantalum nitride, or sapphire. The seed layer 704 may have any suitable pattern without deviating from the scope of the present disclosure.

The second superconductor layer 708 may have a second resistivity and a second superconducting gap. The second superconducting gap may be greater than the first superconducting gap, such as seven times greater than the first superconducting gap. The second superconductor layer 708 may have a thickness that is greater than the first superconductor layer 706. The second superconductor layer 708 may have a thickness of about 50 nm to about 150 nm, such as about 100 nm.

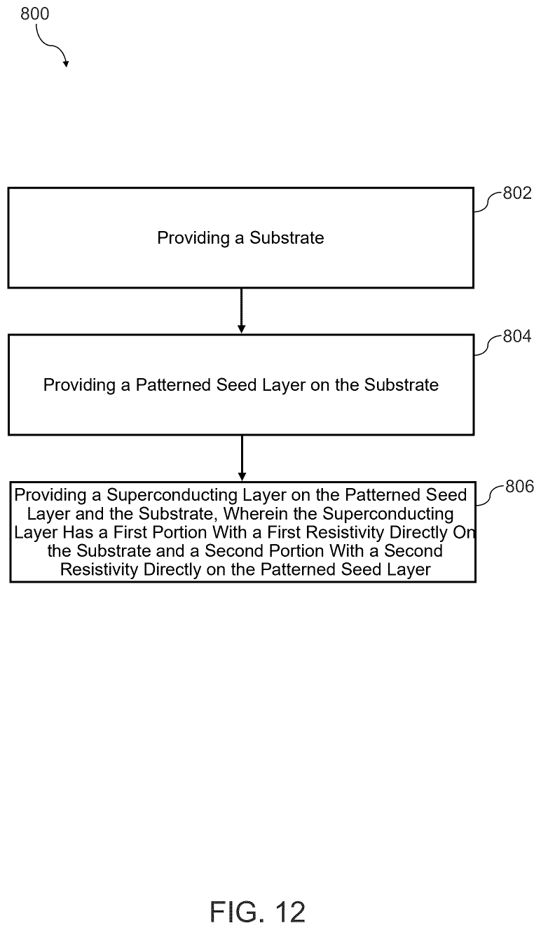

FIG. 12 depicts an example method for purposes of illustration and discussion. Those of ordinary skill in the art, using the disclosures provided herein, will understand that operations of any of the methods described herein can be expanded, include steps not illustrated, omitted, rearranged, and/or modified in various ways without deviating from the scope of the present disclosure. Method 800 of FIG. 12 may be employed to fabricate any superconducting structure and/or resonator structure described herein, including but not limited to the structures discussed in conjunction with FIGS. 1-11.

Method 800 begins at 802 where a substrate is provided. The substrate may be, for instance, a semiconductor wafer and may act as a growth surface and/or deposition surface. The substrate may include silicon, sapphire, germanium, or other suitable material.

At 804 a patterned seed layer is provided on the substrate. The patterned seed layer may be provided directly on the substrate. The patterned seed layer may act as a seed for growth and/or deposition of a superconductor layer (e.g., tantalum). The patterned seed layer may be tantalum nitride, chromium, niobium, alpha phase tantalum, alpha phase tantalum nitride, or sapphire. The patterned seed layer may have any suitable pattern without deviating from the scope of the present disclosure. Example patterns are illustrated in FIGS. 4-7.

At 806 a superconducting layer may be provided on the patterned seed layer and the substrate. The superconducting layer may have a first portion with a first resistivity and/or a first superconducting gap and a second portion with a second resistivity and/or a second superconducting gap. The first portion may be, for instance, beta phase tantalum. The second portion may be, for instance, alpha phase tantalum. The first portion may be directly on the substrate. The second portion may be directly on the patterned seed layer.

### Other Disclosure

Implementations of the digital, classical, and/or quantum subject matter and the digital functional operations and quantum operations described in this specification can be implemented in digital electronic circuitry, suitable quantum circuitry or, more generally, quantum computational systems, in tangibly-implemented digital and/or quantum computer software or firmware, in digital and/or quantum computer hardware, including the structures disclosed in this specification and their structural equivalents, or in combinations of one or more of them. The term “quantum computing systems” may include, but is not limited to, quantum computers/computing systems, quantum information processing systems, quantum cryptography systems, or quantum simulators.

Implementations of the digital and/or quantum subject matter described in this specification can be implemented as one or more digital and/or quantum computer programs (e.g., one or more modules of digital and/or quantum computer program instructions encoded on a tangible non-transitory storage medium for execution by, or to control the operation of, data processing apparatus). The digital and/or quantum computer storage medium can be a machine-readable storage device, a machine-readable storage substrate, a random or serial access memory device, one or more qubits/qubit structures, or a combination of one or more of them. Alternatively or in addition, the program instructions can be encoded on an artificially-generated propagated signal that is capable of encoding digital and/or quantum information (e.g., a machine-generated electrical, optical, or electromagnetic signal) that is generated to encode digital and/or quantum information for transmission to suitable receiver apparatus for execution by a data processing apparatus.

The terms quantum information and quantum data refer to information or data that is carried by, held, or stored in quantum systems, where the smallest non-trivial system is a qubit (i.e., a system that defines the unit of quantum information). It is understood that the term “qubit” encompasses all quantum systems that may be suitably approximated as a two-level system in the corresponding context. Such quantum systems may include multi-level systems, e.g., with two or more levels. By way of example, such systems can include atoms, electrons, photons, ions or superconducting qubits. In many implementations the computational basis states are identified with the ground and first excited states, however it is understood that other setups where the computational states are identified with higher level excited states (e.g., qubits) are possible.

The term “data processing apparatus” refers to digital and/or quantum data processing hardware and encompasses all kinds of apparatus, devices, and machines for processing digital and/or quantum data, including by way of example a programmable digital processor, a programmable quantum processor, a digital computer, a quantum computer, or multiple digital and quantum processors or computers, and combinations thereof. The apparatus can also be, or further include, special purpose logic circuitry, e.g., an FPGA (field programmable gate array), or an ASIC (application-specific integrated circuit), or a quantum simulator, i.e., a quantum data processing apparatus that is designed to simulate or produce information about a specific quantum system. In particular, a quantum simulator is a special purpose quantum computer that does not have the capability to perform universal quantum computation. The apparatus can optionally include, in addition to hardware, code that creates an execution environment for digital and/or quantum computer programs, e.g., code that constitutes processor firmware, a protocol stack, a database management system, an operating system, or a combination of one or more of them.

A digital or classical computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a digital computing environment. A quantum computer program, which may also be referred to or described as a program, software, a software application, a module, a software module, a script, or code, can be written in any form of programming language, including compiled or interpreted languages, or declarative or procedural languages, and translated into a suitable quantum programming language, or can be written in a quantum programming language, e.g., QCL, Quipper, Cirq, etc.

A digital and/or quantum computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A digital and/or quantum computer program can be deployed to be executed on one digital or one quantum computer or on multiple digital and/or quantum computers that are located at one site or distributed across multiple sites and interconnected by a digital and/or quantum data communication network. A quantum data communication network is understood to be a network that may transmit quantum data using quantum systems, e.g. qubits. Generally, a digital data communication network cannot transmit quantum data, however a quantum data communication network may transmit both quantum data and digital data.

The processes and logic flows described in this specification can be performed by one or more programmable digital and/or quantum computers, operating with one or more digital and/or quantum processors, as appropriate, executing one or more digital and/or quantum computer programs to perform functions by operating on input digital and quantum data and generating output. The processes and logic flows can also be performed by, and apparatus can also be implemented as, special purpose logic circuitry, e.g., an FPGA or an ASIC, or a quantum simulator, or by a combination of special purpose logic circuitry or quantum simulators and one or more programmed digital and/or quantum computers.

For a system of one or more digital and/or quantum computers or processors to be “configured to” or “operable to” perform particular operations or actions means that the system has installed on it software, firmware, hardware, or a combination of them that in operation cause the system to perform the operations or actions. For one or more digital and/or quantum computer programs to be configured to perform particular operations or actions means that the one or more programs include instructions that, when executed by digital and/or quantum data processing apparatus, cause the apparatus to perform the operations or actions. A quantum computer may receive instructions from a digital computer that, when executed by the quantum computing apparatus, cause the apparatus to perform the operations or actions.

Digital and/or quantum computers suitable for the execution of a digital and/or quantum computer program can be based on general or special purpose digital and/or quantum microprocessors or both, or any other kind of central digital and/or quantum processing unit. Generally, a central digital and/or quantum processing unit will receive instructions and digital and/or quantum data from a read-only memory, or a random access memory, or quantum systems suitable for transmitting quantum data, e.g. photons, or combinations thereof.

Some example elements of a digital and/or quantum computer are a central processing unit for performing or executing instructions and one or more memory devices for storing instructions and digital and/or quantum data. The central processing unit and the memory can be supplemented by, or incorporated in, special purpose logic circuitry or quantum simulators. Generally, a digital and/or quantum computer will also include, or be operatively coupled to receive digital and/or quantum data from or transfer digital and/or quantum data to, or both, one or more mass storage devices for storing digital and/or quantum data, e.g., magnetic, magneto-optical disks, or optical disks, or quantum systems suitable for storing quantum information. However, a digital and/or quantum computer need not have such devices.

Digital and/or quantum computer-readable media suitable for storing digital and/or quantum computer program instructions and digital and/or quantum data include all forms of non-volatile digital and/or quantum memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks; and quantum systems, e.g., trapped atoms or electrons. It is understood that quantum memories are devices that can store quantum data for a long time with high fidelity and efficiency, e.g., light-matter interfaces where light is used for transmission and matter for storing and preserving the quantum features of quantum data such as superposition or quantum coherence.

Control of the various systems described in this specification, or portions of them, can be implemented in a digital and/or quantum computer program product that includes instructions that are stored on one or more tangible, non-transitory machine-readable storage media, and that are executable on one or more digital and/or quantum processing devices. The systems described in this specification, or portions of them, can each be implemented as an apparatus, method, or electronic system that may include one or more digital and/or quantum processing devices and memory to store executable instructions to perform the operations described in this specification.

While this specification contains many specific implementation details, these should not be construed as limitations on the scope of what may be claimed, but rather as descriptions of features that may be specific to particular implementations. Certain features that are described in this specification in the context of separate implementations can also be implemented in combination in a single implementation. Conversely, various features that are described in the context of a single implementation can also be implemented in multiple implementations separately or in any suitable sub combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

Aspects of the disclosure have been described in terms of illustrative implementations thereof. Numerous other implementations, modifications, or variations within the scope and spirit of the appended claims can occur to persons of ordinary skill in the art from a review of this disclosure. Any and all features in the following claims can be combined or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein, with “or” being understood as “and/or” unless otherwise indicated. Also, terms such as “based on” should be understood as “based at least in part on.”

Those of ordinary skill in the art, using the disclosures provided herein, will understand that the elements of any of the claims, operations, or processes discussed herein can be adapted, rearranged, expanded, omitted, combined, or modified in various ways without deviating from the scope of the present disclosure. Some of the claims are described with a letter reference to a claim element for exemplary illustrated purposes and is not meant to be limiting. The letter references do not imply a particular order of operations. For instance, letter identifiers such as (a), (b), (c), . . . , (i), (ii), (iii), . . . , etc. can be used to illustrate operations. Such identifiers are provided for the ease of the reader and do not denote a particular order of steps or operations. An operation illustrated by a list identifier of (a), (i), etc. can be performed before, after, or in parallel with another operation illustrated by a list identifier of (b), (ii), etc.

What is claimed is:

1. A superconducting structure, comprising:
a substrate;
a patterned seed layer on the substrate; and
a superconducting layer on the patterned seed layer and the substrate, wherein the superconducting layer has a first portion with a first resistivity directly on the substrate and a second portion with a second resistivity directly on the patterned seed layer.

2. The superconducting structure of claim 1, wherein the superconducting layer comprises tantalum.

3. The superconducting structure of claim 2, wherein the first portion comprises beta phase tantalum and the second portion comprises alpha phase tantalum.

4. The superconducting structure of claim 1, wherein the patterned seed layer comprises tantalum nitride.

5. The superconducting structure of claim 1, wherein the patterned seed layer comprises chromium, niobium, alpha phase tantalum nitride, or sapphire.

6. The superconducting structure of claim 1, wherein the substrate comprises silicon.

7. The superconducting structure of claim 1, wherein the substrate comprises sapphire or germanium.

8. The superconducting structure of claim 1, wherein the patterned seed layer comprises a hexagonal pattern.

9. The superconducting structure of claim 1, wherein the patterned seed layer comprises a banded pattern.

10. The superconducting structure of claim 1, wherein the superconducting structure comprises a resonator.

11. The superconducting structure of claim 1, wherein the superconducting structure comprises a quasiparticle or a phonon trap.

12. The superconducting structure of claim 1, wherein the first resistivity is greater than the second resistivity.

13. The superconducting structure of claim 1, wherein at least a portion of the superconducting layer is superconducting at temperatures of less than 3K.

14. A method for forming a superconductor comprising:
providing a substrate;
providing a patterned seed layer on the substrate; and
providing a superconducting layer on the patterned seed layer and the substrate, wherein the superconducting layer has a first portion with a first resistivity directly on the substrate and a second portion with a second resistivity directly on the patterned seed layer.

15. The method for forming the superconductor of claim 14, wherein the wherein the superconducting layer comprises tantalum.

16. The method for forming the superconductor of claim 15, wherein the first portion comprises beta phase tantalum and the second portion comprises alpha phase tantalum.

17. The method for forming the superconductor of claim 14, further comprising cleaning the superconductor.

18. A quantum computing system, comprising:
a superconducting structure, the superconducting structure comprising:
a substrate;
a first superconductor layer on the substrate;
a seed layer on the first superconductor layer; and
a second superconductor layer on the seed layer, wherein the first superconductor layer has a first resistivity and the second superconductor layer has a second resistivity.

19. The quantum computing system of claim 18, wherein the first superconductor layer comprises beta phase tantalum and the second superconductor layer comprises alpha phase tantalum.

20. The quantum computing system of claim 19, wherein the seed layer comprises tantalum nitride, chromium, niobium, alpha phase tantalum nitride, or sapphire.
